(19) United States
(12) Patent Application Publication
(10) Pub. No.: US 2020/0090736 A1
(43) Pub. Date: Mar. 19, 2020

(54) POWER AWARE PROGRAMMABLE NEGATIVE BIT LINE CONTROL

(71) Applicant: Advanced Micro Devices, Inc., Santa Clara, CA (US)

(72) Inventors: Alex Schaefer, Austin, TX (US); Ravi Jotwani, Austin, TX (US); David Hugh McIntyre, Sunnyvale, CA (US)

(73) Assignee: Advanced Micro Devices, Inc., Santa Clara, CA (US)

(21) Appl. No.: 16/132,003

(22) Filed: Sep. 14, 2018

(51) Int. Cl. G11C 11/419; G11C 11/418; G11C 5/14; G11C 7/12; G11C 7/10

(52) U.S. Cl. CPC G11C 11/419; G11C 11/418; G11C 7/1096; G11C 7/12; G11C 5/145

(57) ABSTRACT

A write driver includes a first write data driver, a second write driver, and a control circuit. The first (second) write data driver provides a true (complement) write data signal to an output thereof at a high voltage when a true (complement) data signal is in a first logic state, at a ground voltage when the true (complement) data signal is in a second logic state and a negative bit line enable signal is inactive, and at a voltage below the ground voltage when the true (complement) data signal is in the second logic state and the negative bit line enable signal is active. The control circuit provides the negative bit line enable signal in an active state when a power supply voltage is below a first threshold, and in an inactive state when the power supply voltage is above a second threshold higher than the first threshold.

### BACKGROUND

A variety of techniques have been developed to increase the overall processing speed of computer systems. Vast improvements in integrated circuit processing technologies have contributed to the ability to increase computer processing speeds and memory capacity, thereby contributing to the overall improved performance of computer systems. The ability to produce integrated circuits with deep sub-micron features enables the density of electrical components, such as transistors to also increase.

Static random-access memory (SRAM) is a type of semiconductor memory that uses bi-stable latching circuitry to store binary bits of data. SRAM cells have the advantage of holding data without requiring a refresh. SRAM is still volatile in the sense that data is eventually lost when the memory is not powered. The smallest memory-array unit of a SRAM chip is the subarray, consisting of rows and columns. An addressed cell is at the intersection of a specified row and column address. In SRAM terminology the rows are named word lines and the columns are named bit lines. Bit lines are typically “metallic” conductors perpendicular to the word lines and are physically connected to the source/drains of the cell-transistors. In other words, the bit lines are the lines through which information is written/read to/from the memory cells.

Modern processors operate at relatively low voltages for some workloads to save power. Additionally, modern processors operate at higher voltages to support higher clock speeds for other workloads. To operate embedded memory arrays at low voltages, modern processors often implement a write assist technique using a common method that preserves cell stability called negative bit line boost. However, if the SRAM array operates at too high of a voltage, the voltage across transistors in the bit cells connected to each column multiplexed bit line pair may cause reliability issues such as time-dependent dielectric breakdown, hot carrier injection negative bias temperature instability, positive bias temperature instability, etc.

### BRIEF DESCRIPTION OF THE DRAWINGS

FIG. 1 illustrates in block diagram form an accelerated processing unit (APU) according to some embodiments;

FIG. 2 illustrates in block diagram form a data processor having a multi-chip memory system suitable for use in the APU of FIG. 1;

FIG. 3 illustrates in block diagram form a system on a chip (SOC) having a system management unit (SMU) suitable for use as the SMU of FIG. 1 according to some embodiments;

FIG. 4 illustrates in partial block and partial circuitry form a programmable bit line boost logic circuit according to some embodiments;

FIG. 5 illustrates a timing diagram showing the operation of the programmable bit line boost logic circuit of FIG. 4 according to some embodiments;

FIG. 6 illustrates a timing diagram showing power supply transitions for the programmable bit line boost logic circuit of FIG. 4 according to some embodiments; and

FIG. 7 illustrates in circuit diagram form a variable-sized charge pump for use in the programmable bit line boost logic circuit of FIG. 4 according to some embodiments.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

As will be described below in one form, a write driver includes a first and a second write driver and a control circuit. When a true data signal is in a first logic state, the first write driver provides a true write data signal to an output at a high voltage. The first write driver provides the true write data signal at a ground voltage when the true data signal is in a second logic state and a negative bit line enable signal is inactive. When the true data signal is in the second logic state and the negative bit line enable signal is active the first write driver provides a voltage below the ground voltage. The second write driver provides a complement write data signal to an output at the high voltage when a complement data signal is in the first logic state. When the complement data signal is in the second logic state and the negative bit line enable signal is inactive the second write driver provides a complement write data signal to the output at the ground voltage. The second write data driver provides a complement write data signal to the output at the voltage below the ground voltage when the complement data signal is in the second logic state and the negative bit line enable signal is active. The control circuit provides the negative bit line enable signal in an active state when a power supply voltage is below a first threshold. Additionally, the control circuit provides the negative bit line enable signal in an inactive state when the power supply voltage is above a second threshold that is higher than the first threshold.

In another form, there is described a method for selectively boosting a differential bit line voltage on a bit line pair in a memory device. Access requests are received at the memory device. The memory device operates according to an initial power supply voltage. In response to detection of a change of a power supply voltage, a selection is made between enabling and disabling a negative bit line enable signal to the memory device. The selection is based at least in part on the power supply voltage. When the initial power supply voltage is below a first threshold the negative bit line enable signal is generated in response to detection of an active operating power state. Additionally, the negative bit line enable signal is generated in response to detecting an inactive operating power state when the initial power supply voltage is above a second threshold that is higher than the first threshold. A selected bit line of a bit line pair is driven to a negative voltage, in response to the negative bit line enable signal.

In yet another form, a memory includes true and complement bit lines forming a bit line pair. The true and complement bit lines are coupled to a plurality of memory cells. A write driver couples to the true and complement bit lines. Each memory cell, of the plurality of memory cells, stores a memory bit according to a differential voltage between the true and complement bit lines when the memory cell is selected during a write cycle. The write driver includes a first write driver, a second write driver, and a control circuit. The first write driver provides a true write data signal to the true bit line at a high voltage when a true data signal is in a first logic state. When the true data signal is in a second logic state and a negative bit line enable signal is inactive, the first write driver provides a true write data signal to the true bit line at a ground voltage. In response to the true data signal being in the second logic state and the negative bit line enable signal being active, the first write driver provides a true write data signal to the true bit line at a voltage below the ground voltage. The second write data driver provides a complement write data signal to the complement bit line at the high voltage when a complement data signal is in the first logic state. When the complement data signal is in the second logic state and the negative bit line enable signal is inactive the second write data driver provides a complement write data signal to the complement bit line at the ground voltage. The second write data driver provides a complement write data signal to the complement bit line at the voltage below the ground voltage when the complement data signal is in the second logic state and the negative bit line enable signal is active. The control circuit provides the negative bit line enable signal in an active state when a power supply voltage is below a first threshold. When the power supply voltage is above a second threshold higher than the first threshold the control circuit provides the negative bit line enable signal in an inactive state.

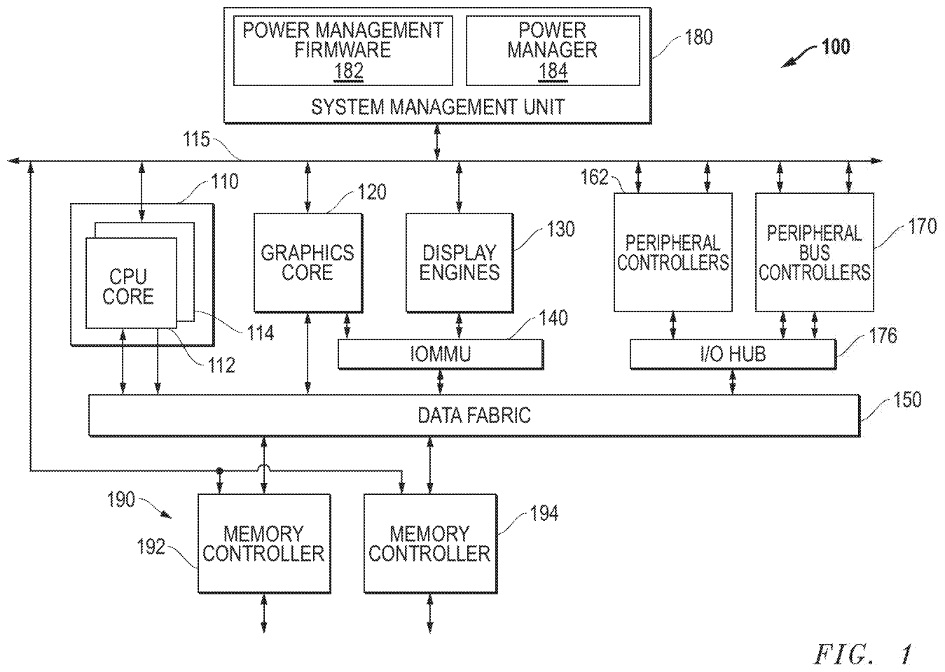

FIG. 1 illustrates in block diagram form an accelerated processing unit (APU) 100. APU 100 includes generally a central processing unit (CPU) core complex 110, a system management network bus 115, a graphics core 120, display engines 130, an input output memory management unit (IOMMU) 140, an interconnect 150, peripheral controllers 162, peripheral bus controllers 170, input output hub 176, a system management unit (SMU) 180, and a memory controller system 190.

CPU core complex 110 includes a CPU core 112 and a CPU core 114. In this example, CPU core complex 110 includes two CPU cores, but in other embodiments CPU core complex 110 can include an arbitrary number of CPU cores. Each of CPU cores 112 and 114 is bidirectionally connected to a system management network (SMN), which forms a control fabric, data fabric 150. Each of CPU cores 112 and 114 is capable of providing memory access requests to interconnect 150. Each of CPU cores 112 and 114 may be unitary cores, or may further be a core complex with two or more unitary cores sharing certain resources such as caches.

Graphics core 120 is a high performance graphics processing unit (GPU) capable of performing graphics operations such as vertex processing, fragment processing, shading, texture blending, and the like in a highly integrated and parallel fashion. Graphics core 120 is bidirectionally connected to the SMN and to data fabric 150 and is capable of providing memory access requests to data fabric 150.

APU 100 may either support a unified memory architecture in which CPU core complex 110 and graphics core 120 share the same memory space, or a memory architecture in which CPU core complex 110 and graphics core 120 share a portion of the memory space, while graphics core 120 also uses a private graphics memory not accessible by CPU core complex 110.

Display engines 130 render and rasterize objects generated by graphics core 120 for display on a monitor. Graphics core 120 and display engines 130 are bi-directionally connected to a common memory management hub 140 for uniform translation into appropriate addresses in a connected memory system, and IOMMU 140 is bi-directionally connected to data fabric 150 for generating such memory accesses and receiving read data returned from the memory system.

Data fabric 150 includes a crossbar switch for routing memory access requests and memory responses between any memory accessing agent and memory controllers 190. It also includes a system memory map, defined by BIOS, for determining destinations of memory accesses based on the system configuration, as well as buffers for each virtual connection.

Peripheral controllers 162 is bi-directionally connected to input/output hub 176. Peripheral controllers 162 can include, for example a USB controller and a SATA interface controller. These two controllers are merely exemplary of peripheral controllers that may be used in APU 100.

Peripheral bus controllers 170 is bi-directionally connected to an input/output (I/O) hub 176 and to the SMN bus. Peripheral bus controllers 170 can include, for example, a system controller or “Southbridge” (SB) and a PCIe controller. I/O hub 176 bi-directionally connects to data fabric 150.

SMU 180 is a local controller that controls the operation of the resources on APU 100 and synchronizes communication among them. SMU 180 is the central thermal and power management controller for a data processing system that utilizes APU 100. SMU 180 includes power management firmware 182 and power manager 184. SMU 180 manages power-up sequencing of the various processors on APU 100 and controls multiple off-chip devices via reset, enable and other signals. SMU 180 includes one or more clock sources not shown in FIG. 1, such as a phase locked loop (PLL), to provide clock signals for each of the components of APU 100. SMU 180 detects variations in operating states of a data processing system. For example, SMU 180 provides variations in the operating states of voltage to power management firmware 182. Power management firmware 182 dynamically enables or disables a negative bit line voltage signal to a memory array of a connected memory device based on an operating voltage of the memory device. Power manager 184 dynamically provides a negative bit line signal to SMN bus 115. The negative bit line signal provided to SMN bus 115 responsively controls operations of the memory array.

Memory controller system 190 includes a set of memory controllers 192 and 194. Memory controllers 192 and 194 are bidirectionally connected to SMN bus 210. A host interface bidirectionally connects memory channel controller 190 to data fabric 150 over a scalable data port (SDP).

APU 100 also implements various system monitoring functions and detects various power management events. In particular, one system monitoring function is the operating voltage at given power states. For example, SMU 180 receives a supply voltage level to be used by a memory device at given power states. Accordingly, SMU 180 selectively enables the negative bit line signal during a descending voltage or disables the negative bit line for an ascending voltage. Further, in one embodiment, SMU 180 selectively reduces the negative bit line voltage as the supply voltage increases to the memory device. Consequently, SMU 180 is able to adaptively determine how much negative bit line is utilized, based on both the power state of the memory and the measured supply voltage, as discussed further below.

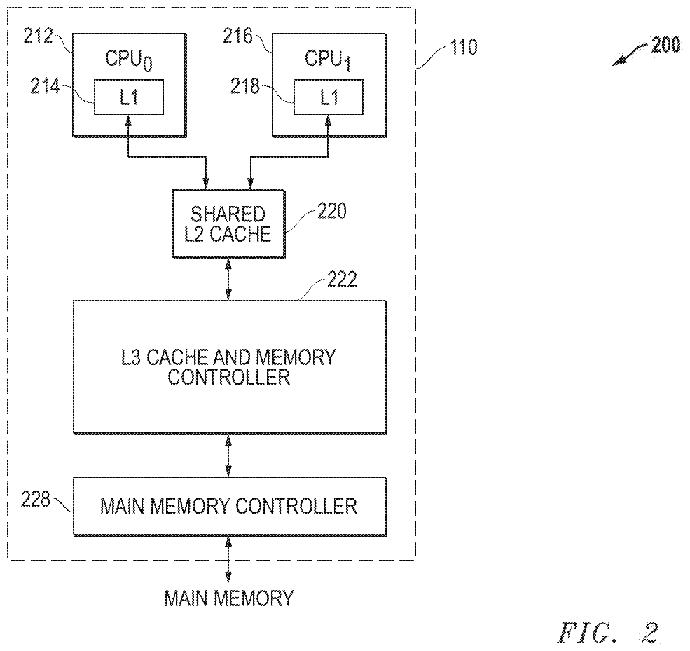

FIG. 2 illustrates in block diagram form a data processor 200 having a multi-chip memory system suitable for use in APU 100 of FIG. 1. Data processor 200 includes generally core complex 110 bidirectionally connected to a main memory. In the example shown in FIG. 2, data processor 200 is a single-chip multi-core processor that includes a first central processing unit (CPU) core 212 labeled “CPUo”, a second CPU core 216 labeled “CPUi”, a shared level-two (L2) cache 220, an L3 cache and memory controller 222, and a main memory controller 228. CPU core 212 includes a level-one (L1) cache 214 and CPU core 216 includes an L1 cache 218.

CPU core 212 has a bidirectional port connected to a first bidirectional port of shared L2 cache 220 over a bidirectional bus. CPU core 216 has a bidirectional port connected to a second bidirectional port of shared L2 cache 220 over a bidirectional bus. Shared L2 cache 220 has a third bidirectional port connected to a first bidirectional port of L3 cache and memory controller 222 over a bidirectional bus. Main memory controller 228 has a second bidirectional port connected to main memory over a bidirectional bus. In the illustrated embodiment, L2 cache 220 is shared between CPU core 212 and 216. In another embodiment, each CPU core 212 and 216 independently utilize a separate L2 cache. Further, other L2 cache and L3 cache configurations can be utilized in the operations of data processor 200.

In the example of FIG. 2, L1 cache 214, L1 cache 218, L2 cache 220 and L3 cache and memory controller 222 can operate at various power-performance states (P-states). In some embodiments, CPU core 212 and CPU core 216 use a separate combination of operational voltage and clock frequency. In other embodiments, each of CPU core 212 and CPU core 216 use a same combination of operational voltage and clock frequency. The combination of operational voltage and clock frequency is referred to as the P-state.

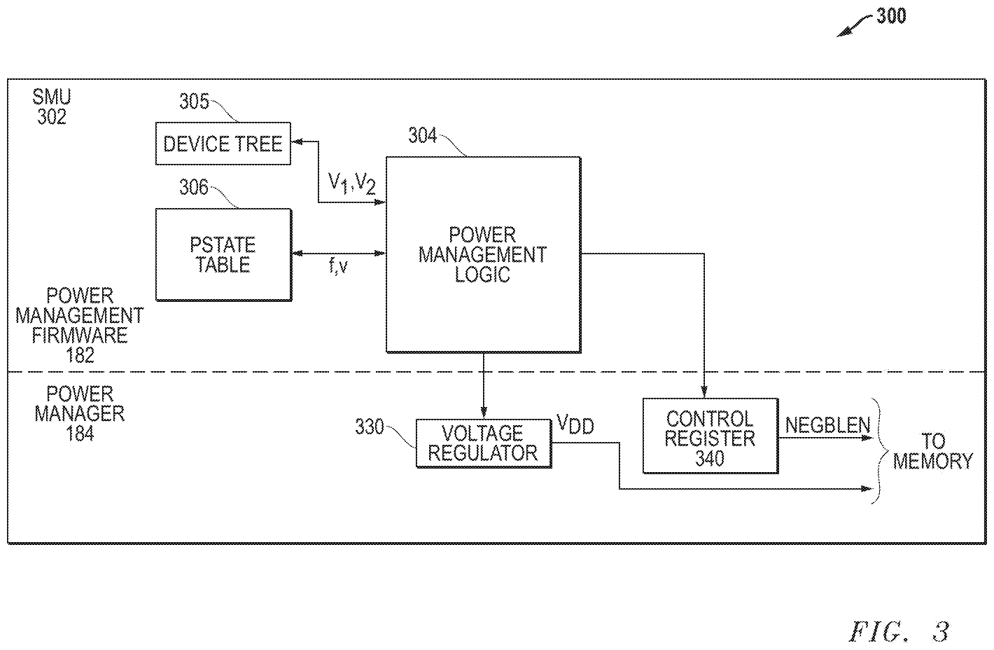

FIG. 3 illustrates in block diagram form a system on a chip (SOC) 300 having an SMU suitable for use such as SMU 180 of FIG. 1, according to some embodiments. SOC 300 includes, at least in part, SMU 302. SMU 302 includes power management firmware 212 and power manager 216. Power management firmware 212 includes power management logic 304 and a P-state table 306. Power management logic 304 has a bidirectional connection to device tree 305. Further, power management logic 304 has a bi-directional connection to P-sate table 306, and an output. P-state table 306 has frequency and voltage values that correspond to the current memory state. Power manager 216 includes voltage regulator 330 which has an input connected to power management logic 304, and an output to memory. Power manager 216 also includes a control register 340 for receiving the NEGBLEN signal from power management logic 304, and an output.

In operation, power management logic 304 changes P-states based, in part, on the utilization of processors associated with APU 100, for example, CPU core 112 and a CPU core 114. Power management logic 304 controls the sequencing of frequency and supply voltage (V_{DD}) changes to effect the P-state changes. When increasing P-states, power management logic 304 increases the V_{DD} accordingly, and then systematically increases the frequency. Device tree 305 provides a first threshold voltage (V₁) and a second threshold voltage (V₂) to power management logic 304. Device tree 305 is a data structure that describes the operating parameters of hardware components associated with APU 100. In one embodiment, SMU 302 periodically measures or polls for the operating voltage associated with the memory. Based on the measurement, power management logic 304 generates logic to control register 340. The logic to control register 340 enables assertion of negative bit line enable (NEGBLEN) signal in response to detecting an inactive operating power state when V_{DD} is above a second threshold that is higher than the first threshold. Responsively, control register 340 provides a digital control signal, or NEGBLEN signal, to the memory that drives a selected bit line of a bit line pair within the memory to a negative voltage during write cycles. The memory can be, for example at least one of L1 cache 214, 218 and L2 cache 220, and L3 cache (and memory controller) 222.

In one embodiment, voltage regulator 330 outputs the initial power supply voltage, V_{DD}, to memory, based on logic provided by power management logic 304. Power management logic 304 selects between enabling and disabling the NEGBLEN signal, to the memory device based at least in part on voltage transitions associated with V_{DD}. Power management logic 304 provides the NEGBLEN signal (to be asserted via control register 340) in the active state when V_{DD} is between V₁ and V₂. In response to a transition from the low voltage to the high voltage, power management logic 304 provides the negative bit line in an inactive state. In one embodiment V₁ and V₂ are predetermined threshold voltages. In another embodiment, V₁ and V₂ are a dynamically determined voltage. Power management logic 304 operates as a control circuit for selectively providing the negative bit line enable signal. The control circuit applies the negative bit line enable signal in an active state when V_{DD} is below a first threshold. The control circuit applies the NEGBLEN signal in an inactive state when V_{DD} is above a second threshold that is higher than the first threshold. The control circuit provides the negative bit line enable signal during write operations, enabling a non-asserted bit line voltage to lower below ground voltage during the write operations. Selectively enabling assertion of the NEGBLEN signal when the power supply voltage and operating frequency is low enough rather than at high operating voltages and turbo frequencies advantageously protects the memory device from voltage spikes and thereby mitigates degradation of the circuit. Further switching NEGBLEN signal off during the higher turbo frequencies/voltages and on for low frequencies/voltages diminishes circuit reliability complications in the memory device. In still another embodiment, to maintain V₁ and V2 >0, and avoid hysteresis switching NEGBLEN on/off close to a single threshold, a Schmitt trigger or other single-threshold solution is utilized.

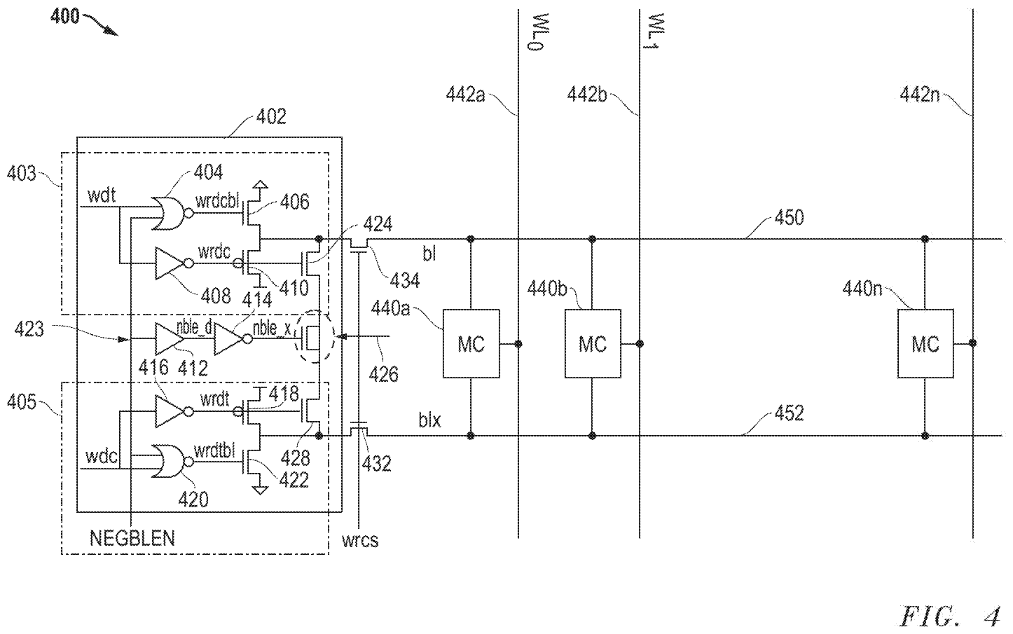

FIG. 4 illustrates in partial block and partial circuitry form a programmable bit line boost logic circuit 400 according to some embodiments. Programmable bit line boost logic circuit 400 includes, generally, write driver 402, negative charge pump 423, memory cells 440a-n, word lines 442a-n, true bit lines 450, and compliment bit line 452. Write driver 402 includes a first write driver 403 and a second write driver 405.

First write data driver 403 includes a NOR gate 404 that has a first input for receiving a true data signal, “wdt”. NOR gate 404 has a second input for receiving the negative bit line enable signal, “NEGBLEN”, and an output. First write data driver 403 also includes an inverter 408 that has an input for receiving the true data signal and an output. A pulldown transistor 406 has an input for receiving the power supply voltage, a gate connected to the output of NOR gate 404, and a drain forming an output of first write data driver 403. A pullup transistor 410 has a source connected to the drain of pulldown transistor 406. Further, pullup transistor 410 has a gate connected to the output of inverter 408, and a drain for receiving the ground voltage.

Second write data driver 405 includes a NOR gate 420 that has a first input for receiving compliment data signal, “wdc”. NOR gate 420 has a second input for receiving the negative bit line enable signal, and an output. Second write driver also includes an inverter 416. Inverter 416 has an input for receiving the compliment data signals, and an output. A pulldown transistor 422 has a source for receiving the power supply voltage, a gate connected to the output of NOR gate 420, and a drain forming the output of second write data driver 405. Further, pullup transistor 418 has a gate connected to the output of inverter 416, and a drain for receiving the ground voltage.

Negative charge pump 423 includes, in part, a delay driver that includes buffer 412 and inverter 414. Buffer 412 has an input for receiving the negative bit line enable signal, and an output. Inverter 414 has an input for receiving the output of buffer 412, and an output that forms the output of the delay driver. A capacitor 426 has a first terminal connected to the output of the delay driver, and a second terminal. A multiplexer, which includes a first multiplexer transistor 423 and a second multiplexer transistor 428. First multiplexer transistor 424 has a source connected to the output of first write data driver 403. Further, first multiplexer transistor 424 has a gate connected to the output of inverter 408, and a drain connected to the second terminal of capacitor 426. Second multiplexer transistor 428 has a source connected to the output of second write data driver 405. Second multiplexer transistor 428 has a gate connected to the output of inverter 416, and a drain connected to the second terminal of capacitor 426. The multiplexer is for selectively coupling the power supply voltage at the second terminal of capacitor 426 to a respective one of the output of first write data driver 403 and second write data driver 405 in response to values of the true, “wdt”, and complement, “wdc” data signals.

A bit line transistor 434 has a source connected to the output of first write driver 403, and a gate for receiving a write compliment signal (wrcs). The drain of bit line transistor 434 connects to true bit line 450. A complimentary bit line transistor 432 has a source connected to the output of second write data driver 405. Complimentary bit line transistor 432 has a gate for receiving the wrcs and a drain that connects to complimentary bit line 452. Memory cells 440a-n are a plurality of memory cells that connect to true bit line 450 and complement bit line 452.

In general, power management logic 304 asserts the NEGBLEN signal during a write cycle. The NEGBLEN signal dynamically lowers the bit line voltage below ground voltage during predetermined operating power states. Based on assertion of the NEGBLEN signal, write driver 402 provides a boost voltage to the memory cell in an active state when a power supply voltage is below a first threshold. The control circuit provides the negative bit line voltage to the memory cell in an inactive state when the power supply voltage is above a second threshold that is higher than the first threshold. Each memory cell stores a memory bit according to a differential voltage between true bit line 450 and complement bit line 452 pairs when selected during a write cycle.

In operation, in response to receiving a request for write operation to a memory cell (440a-n), the NEGBLEN signal asserts. When the NEGBLEN signal asserts first write data driver 403, second write data driver 405, and charge pump 423 receive the NEGBLEN signal from SMU 302. One of true bit line 450 and complement bit line 452 remains high as a precharged bit line, and the other bit line (in the pair) pulls low. Responsively, the write driver that pulls low turns off. For example, in response to a one bit on the input of NOR gate 404, pulldown transistor 406 receives a zero input at the gate, deactivating pulldown transistor 406 and turning off write driver 403. Concurrently, a rising edge at the gate of capacitor 426 initiates a switch capacitor event, or charge injection, that pulls the respective bit line, compliment bit line 452 to a voltage that is below V_{SS}. Accordingly, a boost voltage is applied across the transmission gate of compliment bit line 452 as gate-to-source voltage (V_{GS}), and is high enough to generate a voltage difference that is greater than V_{SS}. When the voltage of compliment bit line 452 is below V_{SS}, second write driver 405 can efficiently write to memory cell 440a.

In one embodiment, programmable bit line boost logic circuit 400 manages the amount of boost voltage a bit line receives when power management logic 304 asserts the NEGBLEN signal. In response to the VGS at a respective bit line going below V_{SS}, the respective memory cell (e.g. 440a-440n) operates in a safe voltage range as long as V_{SS} is below a predetermined “low” voltage. In response to a predetermined “high” V_{SS}, the respective memory cell experiences reliability issues. Programmable bit line boost logic circuit 400 enables charge pump 423 to selectively manage the boost voltage so that the voltage input across the respective memory cell advantageously protects the memory cell from failing. Charge pump 423 controls how much voltage is generated across a respective memory cell based on the value of capacitor 426. Therefore, the value of capacitor 426 is selected to decrease the boost voltage when V_{SS} is at a predetermined high voltage and increase the boost voltage when V_{SS} is at a predetermined low voltage. In another embodiment, when V_{SS} is highest, there is no boost voltage generated to the respective bit line. In one embodiment, true bit line 450 and compliment bit line 452 are driving 6T SRAM bit cells. In another embodiment, true bit line 450 and compliment bit line 452 drive 8T SRAM bit cells. Programmable bit line boost logic circuit 400 detects a write operation at a respective memory cell (440a). True bit line 450 stays precharged, while compliment bit line 452 pulls low. In response to the NEGBLEN signal being asserted inverter 416 turns off, if there is a “1” on NOR gate 420, transistor 418 is deactivated. The NEGBLEN signal passes to negative charge pump 423. A rising edge at second write data driver 405 creates a falling edge at negative charge pump 423 initiating a charge injection that couples compliment bit line 452 below V_{SS}. True bit line 450 stays high. Once compliment bit line 452 is low memory cell 440a is written to.

Memory devices such as memory cell 440a selectively experience a voltage difference that is greater than V_{DD}. A voltage difference greater than V_{DD} is not disruptive to a cell when V_{DD} is a low voltage. However, at a high V_{DD} the voltage difference may cause reliability issues to ensue. Selectively asserting the NEGBLEN signal at low voltages and disabling the NEGBLEN signal at high voltages advantageously enables safe and reliable operation of SRAM memory cells for a broad range of voltages.

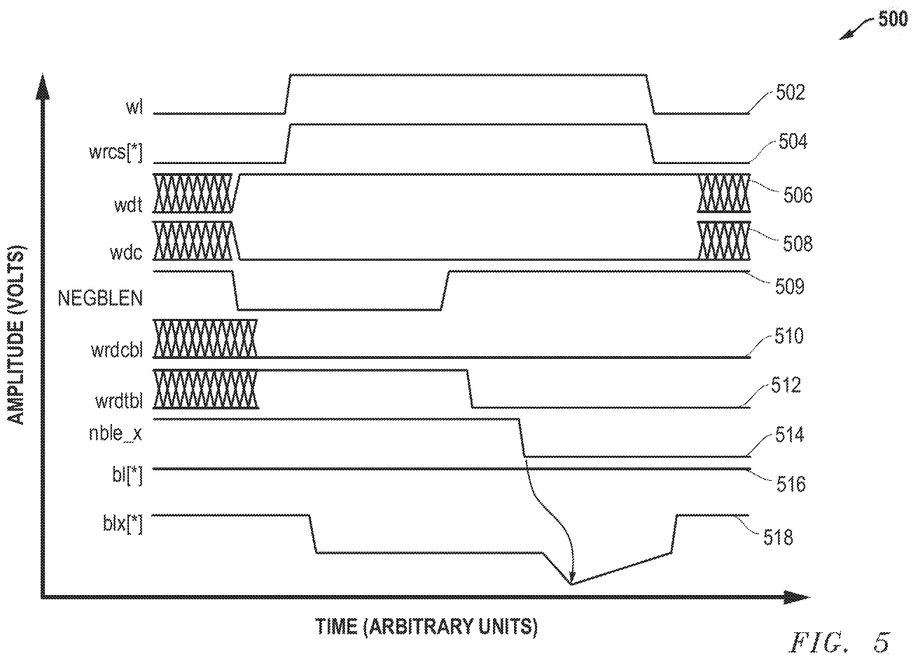

FIG. 5 illustrates a negative bit line timing diagram 500 for the programmable bit line boost logic circuit of FIG. 4 according to some embodiments. Negative bit line timing diagram 500 is utilized to further describe the activity of programmable bit line boost logic circuit 400 includes word line (wl) signal 502, write column select (wrcs) signal 504, wdt signal 506, wdc signal 508, NEGBLEN signal 509, word line compliment bit line (wrdcbl) signal 510, word line true bit line (wrdtbl) signal 512, negative bit line charge pump (nble_x) signal 514, true bit line (bl[*]) signal 516, and compliment bit line (blx[*]) signal 518.

In one embodiment, first write data driver 403 provides wdt signal 506 to the output at a high voltage when wdt signal 506 is in a first logic state. When wdt signal 506 is in a second logic state and NEGBLEN signal 509 is inactive, first write data driver 403 provides wdt signal 506 to the output at a ground voltage. First write data driver 403 provides wdt signal 506 to the output at a voltage below the ground voltage when wdt signal 506 is in the second logic state and NEGBLEN signal 509 is active. Second write data driver 405 provides wdc signal 508 to the output at the high voltage when wdc signal 508 is in the first logic state. When wdc signal 508 is in the second logic state and NEGBLEN signal 509 is inactive, second write data driver 405 provides wdc signal 508 to the output at the ground voltage. Second write data driver 405 provides wdc signal 508 to the output at the ground voltage and at the voltage below the ground voltage when wdc signal 508 is in the second logic state and NEGBLEN signal 509 is active. Negative charge pump 423, connected at the output of first write data driver 403 and second write data driver 405 selectively provides a negative bit line voltage signal to true bit line 450 and complement bit line 452 pairs, leaving a second bit line of the bit line pair in a precharged state.

In another embodiment, there is a charge of V_{DD} to zero volts across capacitor 426. In response to power management logic 304 asserting a high NEGBLEN signal 509 (input “1”), the high signal passes through buffer 412 and inverter 414 and outputs a low (output “0”) signal at capacitor 426. Consequently, nble x signal 516 goes low and capacitor 426 resists the instantaneous change in voltage. To maintain the voltage difference across the plates of capacitor 426, capacitor 426 pulls the respective node below ground. The signal activity is illustrated in FIG. 5. In response to nble_x signal 514 going low, blx[*] signal 518 on complement bit line 452 advantageously pulls below ground generating enough separation between the voltages at bit line 450 and compliment bit line 452 to flip the respective memory cell during the write cycle specifically during periods of low voltage supply to the memory device. As illustrated, wrdtbl signal 512 goes low before nble x signal 516 goes low to trigger the negative bit line event. Otherwise, NFET 422 will conduct and reduce the negative boost.

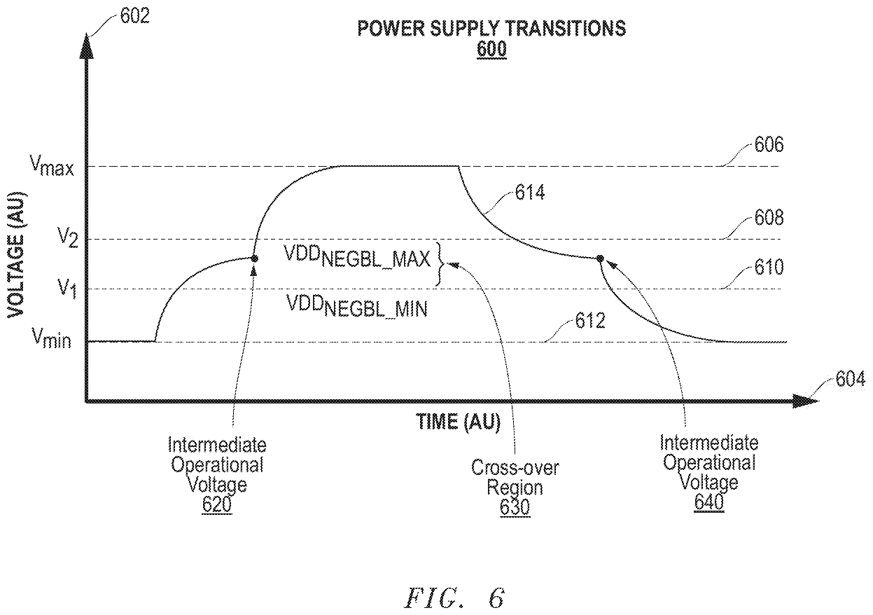

Referring now to FIG. 6, which illustrates power supply transitions for the programmable bit line boost logic circuit of FIG. 4 according to some embodiments. Power supply transitions diagram 600 includes a voltage axis 602, a time axis 604, maximum voltage (Vₘₐₓ) 606, first threshold 608, second threshold 610, minimum voltage (Vₘᵢₙ) 612, and power supply voltage 614. Further, power supply transitions diagram 600 includes an intermediate operational voltage 620, a cross-over region 630, and an intermediate operational voltage 640.

In one embodiment, the memory device has a maximum rated operating voltage, Vₘₐₓ 606, and a minimum rated operating voltage, Vₘᵢₙ 612. Vₘₐₓ 606 and Vₘᵢₙ 612 are predetermined voltages. Power management logic 304 enables the NEGBLEN signal to be asserted at low voltages and disables the NEGBLEN signal at high voltages. At a middle voltage range (between first voltage threshold 610 and second voltage threshold 608), where bit cells do not require a write assist to write data, enabling the NEGBLEN signal will not enable a voltage across the memory cell to exceed Vₘₐₓ 606. Accordingly, the cross-over region 630, at a point such as intermediate operational voltage 620, is a safe region to disable the NEGBLEN signal when ascending from Vₘᵢₙ 612 to Vₘₐₓ 606. Similarly, intermediate operational voltage 640, is a safe region to enable the NEGBLEN signal when descending from Vₘₐₓ 606 to Vₘᵢₙ 612. Further, cross-over region 630 implements a voltage gap that enables hysteresis when switching to avoid continuously toggling NEGBLEN in the event that power supply voltage 614 is in close proximity to a single threshold.

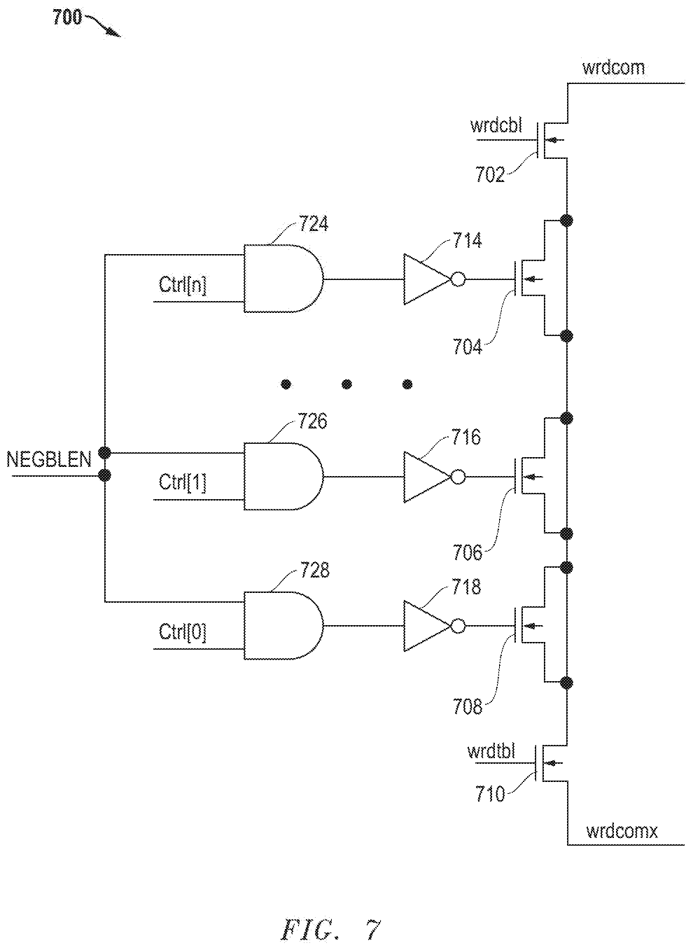

FIG. 7 illustrates in circuit form a variable-sized charge pump 700 for use in the programmable bit line boost logic circuit of FIG. 4 according to some embodiments. Variable-sized charge pump 700 includes AND gate 724, 726, and 728 which have a first input for receiving a NEGBLEN signal, a second input for receiving a control signal, and an output. Inverter 714, 716, and 718 include an input for respectively receiving a signal from each output of AND gate 724, 726, and 728, and an output. A charge pump transistor 702 has a gate for receiving the wrdcbl signal, a drain for providing the wrdcom signal, and a source. A set of capacitors 704, 706, and 708 are formed by N-channel MOS transistors whose sources and drains are connected together, and whose gates are selectively enabled. Capacitor 704 has a first terminal connected to the output of inverter 714, and a second terminal connected to the source of charge pump transistor 702. Capacitor 706 has a first terminal connected to the output of inverter 716, and a second terminal connected to the source of charge pump transistor 702. Capacitor 708 has a first terminal connected to the output of inverter 718, and a second terminal connected to the source of charge pump transistor 702. Further, charge pump transistor 710 includes a gate for receiving the wrdtbl signal, a source connected to the source of charge pump transistor 702 and to the second terminals of capacitors 704, 706, and 708, and a drain for providing the wrdcomx signal.

In one embodiment, negative chare pump 423 is modified to provide a programmable charge pump circuit, charge pump 700. Granularity is achieved by modifying the capacitors and inverters of negative charge pump 423 to have multiple capacitors attached to a shared node and controlled by separate signals. The separate signals can be, for example, static signals, fuse signals, or signals controlled by SMU 302. In operation AND gates 724, 726, and 728 can enable or disable the assertion of the negative bit line signal based on control signals respectively input to AND gates 724, 726, and 728. As shown, capacitors 704, 706, and 708 are fused. In another embodiment, capacitors 704, 706, and 708 can be dynamically controlled based on the control voltages input to AND gates 724, 726, and 728. Charge pump 700 determines the number of stages to selectively enable based on an operating power state. Charge pump 700 selectively enables a number of stages of a plurality of parallel connected charge pump stages based on a value of the power supply voltage. In still another embodiment, the capacitors (704, 706, and 708) of charge pump 700 are configured to generate a percentage of the supply voltage as the negative bit line voltage to the memory device.

Charge pump 700 selectively provides the negative bit line voltage to the memory device. A programmable charge pump provides the advantage of reducing the amount of negative bit line voltage as the supply voltage increases. Reducing the negative bit line voltage as the supply voltage increases provides added power savings given that many bit lines are written, and each separate bit line pair requires a negative bit line voltage.

Some or all of the method illustrated in FIGS. 1-7 may be governed by instructions that are stored in a computer readable storage medium and that are executed by at least one processor. Operations shown in FIG. 1-7 may correspond to instructions stored in a non-transitory computer memory or computer readable storage medium. In various embodiments, the non-transitory computer readable storage medium includes a magnetic or optical disk storage device, solid-state storage devices such as Flash memory, or other non-volatile memory device or devices. The computer readable instructions stored on the non-transitory computer readable storage medium may be in source code, assembly language code, object code, or other instruction format that is interpreted and/or executable by one or more processors.

While particular embodiments have been described, various modifications to these embodiments will be apparent to those skilled in the art. Memory controller 192 and 194 may interface to other types of memory besides SRAM memory, such as high bandwidth memory (HBM), RAMbus™ DRAM (RDRAM), and the like. Further, while particular embodiments have been described within APU 100, various modifications to these embodiments will be apparent to those skilled in the art. For example, an artificial intelligence engine can replace GPU 120, or CPU core complex 110 can be implemented without the use of graphics core 120. Although specific details such as specific structures, elements, and connections have been presented herein, it is to be understood that the specific details presented need not be utilized to practice embodiments of the present disclosure. It is also to be understood that other embodiments may be utilized and that logical, architectural, programmatic, mechanical, electrical and other changes may be made without departing from general scope of the disclosure. Accordingly, it is intended by the appended claims to cover all modifications of the disclosed embodiments that fall within the scope of the disclosed embodiments.

What is claimed is:

1. A write driver, comprising:
a first write data driver for providing a true write data signal to an output thereof at a high voltage when a true data signal is in a first logic state, at a ground voltage when the true data signal is in a second logic state and a negative bit line enable signal is inactive, and at a voltage below the ground voltage when the true data signal is in the second logic state and the negative bit line enable signal is active;
a second write data driver for providing a complement write data signal to an output thereof at the high voltage when a complement data signal is in the first logic state, at the ground voltage when the complement data signal is in the second logic state and the negative bit line enable signal is inactive, and at the voltage below the ground voltage when the complement data signal is in the second logic state and the negative bit line enable signal is active; and
a control circuit for providing the negative bit line enable signal in an active state when a power supply voltage is below a first threshold, and in an inactive state when the power supply voltage is above a second threshold higher than the first threshold.

2. The write driver of claim 1, wherein each of the first and second write data drivers comprises:
a NOR gate having a first input for receiving a respective one of the true data signal and compliment data signal, a second input for receiving the negative bit line enable signal, and an output;
an inverter having in input for receiving the respective one of the true data signal and compliment data signals, and an output;
a pulldown transistor having a source for receiving the power supply voltage, a gate coupled to the output of a respective one of the NOR gate, and a drain forming the output of a respective one of the first write data driver and the second write data driver; and
a pullup transistor having a source coupled to a respective one of the drain of the pulldown transistor, a gate coupled to the respective one of the output of the inverter, and a drain for receiving the ground voltage.

3. The write driver, of claim 1, further comprising a negative charge pump.

4. The write driver, of claim 3, wherein the negative charge pump comprises:
a delay driver having an input for receiving the negative bit line enable signal, and an output;
a capacitor having a first terminal coupled to the output of the delay driver, and a second terminal; and
a multiplexer for selectively coupling the power supply voltage at the second terminal of the capacitor to a respective one of the output of the first write data driver and the second write data driver in response to values of the true and complement data signals.

5. The write driver, of claim 3, wherein the negative charge pump is a programmable negative charge pump circuit having a plurality of negative charge pump stages for selectively providing the negative bit line enable signal based on the power supply voltage.

6. The write driver, of claim 1, wherein the high voltage is a predetermined high voltage.

7. The write driver of claim 1, further wherein:
in response to a transition from the high voltage to a low voltage, the write driver further providing the negative bit line enable signal in the active state when the power supply voltage is between the first threshold and the second threshold, wherein the low voltage is a predetermined low voltage; and
in response to a transition from the low voltage to the high voltage, the write driver further providing the negative bit line in an inactive state.

8. A method for selectively boosting a differential bit line voltage on a bit line pair in a memory device, comprising:
receiving access requests at the memory device operating according to an initial power supply voltage;
in response to detection of a change of a power supply voltage, selecting between enabling and disabling a negative bit line enable signal to the memory device based at least in part on the power supply voltage;
generating the negative bit line enable signal in response to detecting an active operating power state, when the initial power supply voltage is below a first threshold, and in response to detecting an inactive operating power state, when the initial power supply voltage is above a second threshold higher than the first threshold; and
driving a selected bit line of a bit line pair to a negative voltage in response to the negative bit line enable signal.

9. The method of claim 8, wherein providing the negative bit line enable signal further comprises selectively providing a negative bit line voltage signal to a first bit line of the bit line pair and leaving a second bit line of the bit line pair in a precharged state.

10. The method of claim 8, further comprises generating the negative bit line enable signal to a charge pump, wherein the charge pump selectively provides the negative bit line enable signal to the memory device.

11. The method of claim 8, further comprising: selectively enabling a number of stages of a plurality of parallel connected charge pump stages in response to the power supply voltage.

12. The method of claim 11, further comprising determining the number of stages to selectively enable based on an operating power state.

13. The method of claim 12, further comprising determining a change in the operating power state based on a power state table.

14. The method of claim 8, wherein generating the negative bit line enable signal comprises generating the negative bit line enable signal for a plurality of pairs of bit lines.

15. The method of claim 8, wherein the memory device comprises at least one of a level one cache, a level two cache, and a level three cache of a static random-access memory device.

16. A memory comprising:
true and complement bit lines forming a bit line pair;
a plurality of memory cells coupled to the true and complement bit lines, each memory cell for storing a memory bit according to a differential voltage between the true and complement bit lines when selected during a write cycle; and
a write driver coupled to the true and complement bit lines comprising:
a first write data driver for providing a true write data signal to the true bit line at a high voltage when a true data signal is in a first logic state, at a ground voltage when the true data signal is in a second logic state and a negative bit line enable signal is inactive, and at a voltage below the ground voltage when the true data signal is in the second logic state and the negative bit line enable signal is active;
a second write data driver for providing a complement write data signal to the complement bit line at the high voltage when a complement data signal is in the first logic state, at the ground voltage when the complement data signal is in the second logic state and the negative bit line enable signal is inactive, and at the voltage below the ground voltage when the complement data signal is in the second logic state and the negative bit line enable signal is active; and
a control circuit for providing the negative bit line enable signal in an active state when a power supply voltage is below a first threshold, and in an inactive state when the power supply voltage is above a second threshold higher than the first threshold.

17. The memory, of claim 16, wherein the write driver further comprising a negative charge pump for providing the voltage below the ground voltage to a respective one of the bit line pairs.

18. The memory, of claim 17, wherein the negative charge pump is a programmable negative charge pump circuit having a plurality of negative charge pump stages.

19. The memory, of claim 18, wherein the programmable negative charge pump circuit provides the negative bit line enable signal to a selected bit line of the bit line pair based on the power supply voltage.

20. The memory, of claim 16, wherein the high voltage is a predetermined high voltage, and the first and second threshold are predetermined thresholds between the high voltage and a predetermined low voltage.
